(19) United States
(12) Patent Application Publication
(10) Pub. No.: US 2026/0328969 A1
(43) Pub. Date: Oct. 22, 2026

(54) LAMINATE FOR DISPLAY DEVICE, DISPLAY DEVICE, AND DISPLAY DEVICE EQUIPPED WITH SUPPORT PLATE

(71) Applicant: DAI NIPPON PRINTING CO., LTD., Tokyo (JP)

(72) Inventors: Atsuhiro KOBAYASHI, Tokyo (JP); Kiyohiro TAKACHI, Tokyo (JP); Kazushige HORI, Tokyo (JP); Osamu WATANABE, Tokyo (JP)

(21) Appl. No.: 19/115,672

(22) PCT Filed: Sep. 29, 2023
(86) PCT No.: PCT/JP2023/035677

§ 371 Date: Mar. 26, 2025

(30) Foreign Application Priority Data
Sep. 29, 2022 (JP) 2022-156246

(51) Int. Cl. G02B 1/14; G02B 1/18; H04M 1/02

(52) U.S. Cl. CPC G02B 1/14; G02B 1/18; H04M 1/0235; H04M 1/0268; H04M 2250/22

(57) ABSTRACT

The present disclosure provides a stacked body for a display device comprising: a resin substrate; a hard coating layer disposed on one surface of the resin substrate; and a resin layer disposed on a surface of the resin substrate that is opposite side to the hard coating layer, wherein an indenter push-in amount of a cross-section of the resin layer is 200 nm or more and 3000 nm or less; the indenter push-in amount of a cross-section of the resin substrate is less than the indenter push-in amount of a cross-section of the resin layer; a thickness of the resin layer is 5 μm or more and 45 μm or less; and a total thickness of the resin substrate and the resin layer is 50 μm or more and 130 μm or less.

### TECHNICAL FIELD

The present disclosure relates to a stacked body for a display device, a display device and a display device provided with a supporting plate.

### BACKGROUND ART

For example, a stacked body for a display device having various properties such as a hard coating property, an abrasion resistance, antireflection property, an antiglare property, an antistatic property, and an antifouling property, is disposed, as a front plate, on the surface of a display device.

As such a stacked body for a display device, for example, Patent Document 1 discloses a stacked body for a display device comprising an impact absorbing layer, a supporting body, and a functional layer, wherein the thickness of the impact absorbing layer is 1 μm or more; and in the impact absorbing layer, a maximum value of a ratio (tan δ) of a loss elastic modulus with respect to a storage elastic modulus in a frequency range of 10 to 105 Hz at 25° C. is 2.0 or less.

Meanwhile, flexible display devices such as foldable displays, rollable displays, bendable displays, and slidable displays have recently been attracting attention, and the development of the stacked body for a display device disposed on the surface of the flexible display devices has been actively promoted. Above all, the slidable displays can expand the size of the screen by sliding the display so that the sliding displays have been attracting particular attention in recent years.

### CITATION LIST

### Patent Document

Patent Document 1: Japanese Patent Application Laid-Open (JP-A) No. 2021-14014

### SUMMARY OF DISCLOSURE

### Technical Problem

The stacked body for a display device disposed on the surface of the flexible display device is required to have chafing resistance. Therefore, a stacked body for a display device including a hard coating layer is considered to be used. Among the flexible display devices, folding type foldable displays are required to not involve display defects even if they are bent repeatedly, and stacked bodies for a display device disposed on the surface of the flexible display devices are required to have bending resistance that does not cause peeling or cracking when they are bent repeatedly.

Meanwhile, when stacked body for a display device including a hard coating layer are used for slidable displays or rollable displays, the following problems, which are different from that of the folding type foldable displays, may occur.

FIG. 2(a) is a schematic front view of a smartphone including a slidable display, and FIG. 2(b) and FIG. 2(c) are A-A schematic cross-sectional views of FIG. 2(a). The smartphone 20 shown in FIG. 2 includes a caterpillar structure X configured to slide the slidable display 21 stored inside the device and send it toward the observer side when the screen is enlarged, and slide the slidable display 21 to store it inside the device when the screen is diminished.

FIG. 3 shows a partial enlarged view of the caterpillar structure X. Specifically, the slidable display 21 is slidable while positioned on the supporting plate S (such as SUS plate). The supporting plate S includes a linear penetration pattern P whose longitudinal direction is perpendicular to the screen enlarging direction, at the region to be a bent portion, to make it easier to bend. As for the caterpillar structure X, the slidable display 21 is generally bent so that the stacked body for a display device, which is the surface material, is on the outer side. Also, since the supporting plate S includes the penetration pattern P, there is a level-difference wherein the curvature is locally high. The level-difference of the supporting plate affects the stacked body for a display device, which is the surface material of the display device.

Therefore, when the stacked body for a display device including a hard coating layer is used as the surface material of a slidable display or a rollable display, a crack may occur in the hard coating layer at the bent portion (hereinafter, may be referred to as a slide bent portion or slide bending) of the caterpillar structure X of the stacked body for a display device; or a floatation may occur to the adhesive layer between the display panel on which the stacked body for a display device is disposed, and the supporting plate.

The present disclosure has been made in view of the above circumstances, and an object of the present disclosure is to provide a stacked body for a display device with good chafing resistance, wherein defects at the slide bent portion are suppressed.

### Solution to Problem

One embodiment of the present disclosure provides a stacked body for a display device comprising: a resin substrate; a hard coating layer disposed on one surface of the resin substrate; and a resin layer disposed on a surface of the resin substrate that is opposite side to the hard coating layer, wherein an indenter push-in amount of a cross-section of the resin layer is 200 nm or more and 3000 nm or less; the indenter push-in amount of a cross-section of the resin substrate is less than the indenter push-in amount of a cross-section of the resin layer; a thickness of the resin layer is 5 μm or more and 45 μm or less; and a total thickness of the resin substrate and the resin layer is 50 μm or more and 130 μm or less.

Another embodiment of the present disclosure provides a display device comprising: a display panel, and the stacked body for a display device described above disposed on an observer side of the display panel, wherein the stacked body for a display device is disposed so that a hard coating layer side is on an observer side.

Another embodiment of the present disclosure provides a display device provided with a supporting plate comprising the display device described above, and a supporting plate disposed on a display panel side surface of the display device, wherein the display device is a flexible display; and the supporting plate includes a penetration pattern passing through in a thickness direction.

### Advantageous Effects of Disclosure

The present disclosure has an effect that a stacked body for a display device with good chafing resistance, wherein defects at the slide bent portion are suppressed, may be provided.

### BRIEF DESCRIPTION OF DRAWINGS

FIG. 1 is a schematic cross-sectional view illustrating an example of a stacked body for a display device in the present disclosure.

FIG. 2(a) is a schematic front view of a smartphone including a slidable display, and

FIG. 2(b) and FIG. 2(c) are A-A schematic cross-sectional views of FIG. 2(a).

FIG. 3 is a partial enlarged view of the caterpillar structure.

FIG. 4 are schematic cross-sectional views illustrating an example of a conventional stacked body for a display device.

FIG. 5 are schematic cross-sectional views illustrating an example of a conventional stacked body for a display device.

FIG. 6 are schematic views for explaining a slide bending test.

FIG. 7 are schematic top views of a supporting plate used for a slide bending test.

FIG. 8 is a schematic cross-sectional view illustrating an example of a display device in the present disclosure.

FIG. 9 is a schematic cross-sectional view illustrating an example of a display device in the present disclosure.

FIG. 10 is a schematic cross-sectional view illustrating an example of a display device provided with a supporting plate in the present disclosure.

### DESCRIPTION OF EMBODIMENTS

Embodiments in the present disclosure are hereinafter explained with reference to, for example, drawings. However, the present disclosure is enforceable in a variety of different forms, and thus should not be taken as is limited to the contents described in the embodiments exemplified as below. Also, the drawings may show the features of the present disclosure such as width, thickness, and shape of each part schematically comparing to the actual form in order to explain the present disclosure more clearly in some cases; however, it is merely an example, and thus does not limit the interpretation of the present disclosure. Also, in the present descriptions and each drawing, for the factor same as that described in the figure already explained, the same reference sign is indicated and the detailed explanation thereof may be omitted.

In the present descriptions, in expressing an aspect wherein some member is placed on the other member, when described as merely “above” or “below”, unless otherwise stated, it includes both of the following cases: a case wherein some member is placed directly on or directly below the other member so as to be in contact with the other member, and a case wherein some member is placed on the upper side or the lower side of the other member via yet another member. Also, in the present descriptions, on the occasion of expressing an aspect wherein some member is placed on the surface of the other member, when described as merely “on the surface side” or “on the surface”, unless otherwise stated, it includes both of the following cases: a case wherein some member is placed directly on or directly below the other member so as to be in contact with the other member, and a case wherein some member is placed on the upper side or the lower side of the other member via yet another member.

A stacked body for a display device and a display device in the present disclosure are hereinafter described in detail.

### A. Stacked Body for Display Device

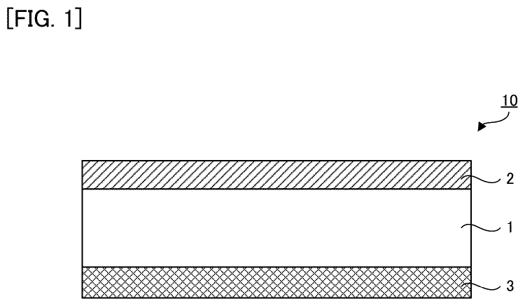

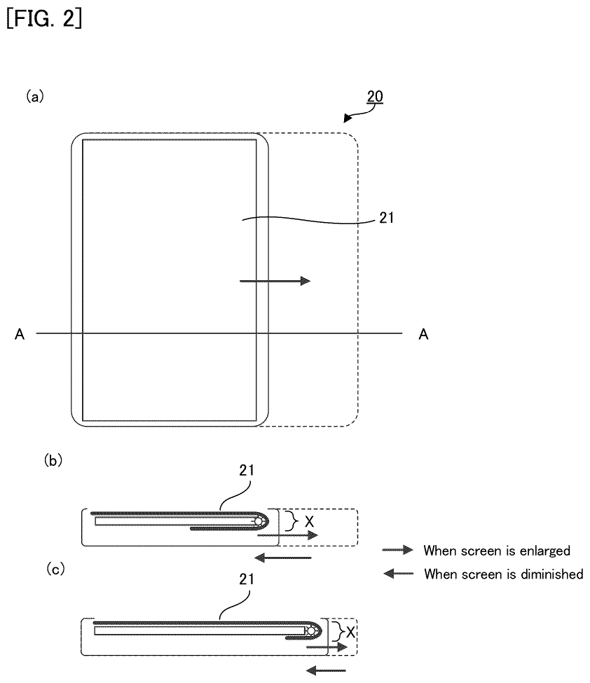

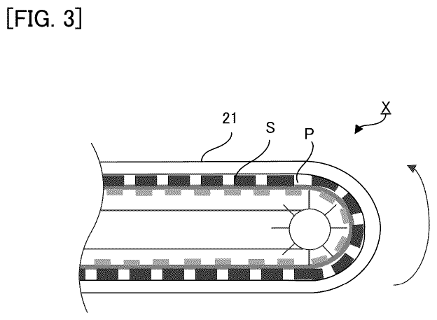

FIG. 1 is a schematic cross-sectional view illustrating an example of a stacked body for a display device in the present disclosure. The stacked body for a display device 10 shown in FIG. 1 comprises: a resin substrate 1; a hard coating layer 2 disposed on one surface of the resin substrate 1; and a resin layer 3 disposed on a surface of the resin substrate 1 that is opposite side to the hard coating layer 2. Also, the indenter push-in amount of a cross-section of the resin layer 3 is 200 nm or more and 3000 nm or less, and the indenter push-in amount of a cross-section of the resin substrate 1 is less than an indenter push-in amount of a cross-section of the resin layer 3. Further, the thickness of the resin layer 3 is 5 μm or more and 45 μm or less, and the total thickness of the resin substrate 1 and the resin layer 3 is 50 μm or more and 130 μm or less.

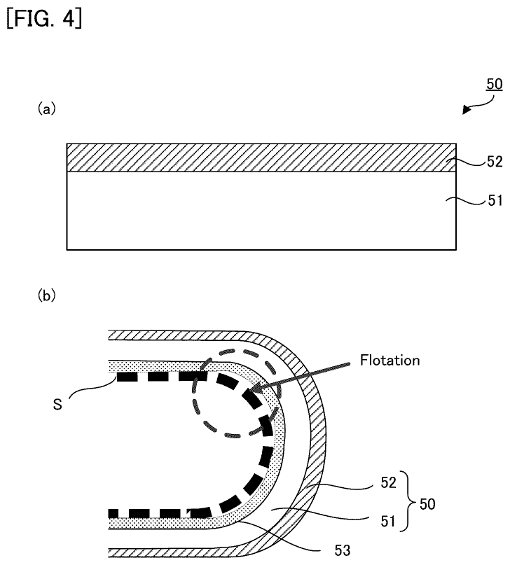

FIG. 4(a) is a schematic cross-sectional view illustrating an example of a conventional stacked body for a display device. The stacked body for a display device 50 shown in FIG. 4(a) comprises a resin substrate 51, and a hard coating layer 52. FIG. 4(b) is an explanation view of a slide bending test that simulates slide bending when using a slidable display, carried out to a test piece wherein a stacked body for a display device 50 is joined together with a supporting plate S via an adhesive layer 53. As shown in FIG. 4(b), in this slide bending test, a problem that the adhesive layer 53 floats from the supporting plate S occurs. The reason therefor is presumed that, since the resin substrate 51 is hard, the resin substrate 51 cannot follow to high curvature existing locally on the supporting plate S. This problem also occurs when using actual slidable displays, and the adhesive layer between the display panel and the supporting plate is peeled off from, for example, the display panel.

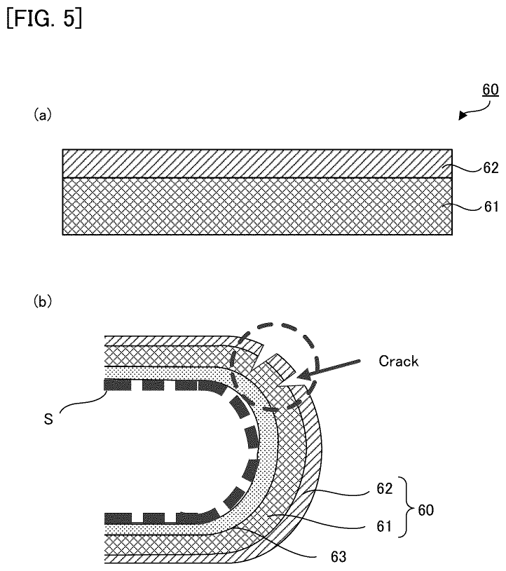

FIG. 5(a) is a schematic cross-sectional view illustrating another example of a conventional stacked body for a display device. The stacked body for a display device 60 shown in FIG. 5(a) comprises a resin layer 61, and a hard coating layer 62. FIG. 5(b) is an explanation view of a slide bending test that simulates slide bending when using a slidable display, carried out to a test piece wherein a stacked body for a display device 60 is joined together with a supporting plate S via an adhesive layer 63. As shown in FIG. 5(b), in this slide bending test, a crack occurs in the hard coating layer 62. The reason therefor is presumed that, although the resin layer 61 follow the level-difference of the supporting plate S, the hard coating layer 62 cannot follow to high curvature existing locally on the supporting plate S so that a crack occurs. This problem also occurs when using actual slidable displays, and a crack occurs in the hard coating layer.

Meanwhile, in the stacked body for a display device in the present disclosure, since the thickness of the resin layer disposed on one surface of the resin substrate is a predetermined value or more, and further, since the indenter push-in amount of a cross-section is a predetermined value or more, it functions as a level-difference absorbing layer. Therefore, the stacked body for a display device can follow the level-difference of the supporting plate when slide bent. Thereby, when the stacked body for a display device in the present disclosure is used as a display device by disposing on the observer side of the display panel, the peeling of the adhesive layer between the supporting plate and the display panel disposed on the surface of the supporting plate constituting the caterpillar structure, via an adhesive layer, in the screen enlarging region of, for example, a slidable display can be suppressed.

Also, since the resin substrate that is harder than the resin layer is disposed, and further, since the total thickness of the resin substrate and the resin layer is a predetermined value or more, it is possible to bring relief to the curvature of the region with high curvature that occurs locally due to the supporting plate that constitutes the caterpillar structure, and prevent the application of high curvature locally to the hard coating layer. Thereby, occurrence of a crack in the hard coating layer can be suppressed.

Further, since the stacked body for a display device in the present disclosure includes a hard coating layer, the thickness of the resin layer is a predetermined value or less, and the resin substrate harder than the resin layer exists, excellent chafing resistance can be obtained. Incidentally, the property that suppresses the defect in the slide bent portion described above is referred to as slide bending resistance.

The stacked body for a display device in the present disclosure comprises: a resin substrate; a hard coating layer disposed on one surface of the resin substrate; and a resin layer disposed on a surface of the resin substrate that is opposite side to the hard coating layer. That is, the stacked body for a display device in the present disclosure includes a resin layer, a resin substrate and a hard coating layer in this order in the stacking direction. The stacked body for a display device in the present disclosure is hereinafter described in detail.

### I. Resin Layer

The resin layer used in the stacked body for a display device in the present disclosure is able to absorb the level-difference caused by the supporting plate that constitutes the caterpillar structure used in the screen enlarging region of, for example, slidable display. Thereby, the peeling between the supporting plate constituting the caterpillar structure, and the display panel disposed on the surface of the supporting plate, via an adhesive layer, in the screen enlarging region of, for example, a slidable display can be suppressed.

### 1. Indenter Push-In Amount of Cross-Section

The indenter push-in amount of a cross-section of the resin layer in the present disclosure is 200 nm or more, preferably 250 nm or more, and more preferably 280 nm or more. When the indenter push-in amount of a cross-section of the resin layer is in the above range, a level-difference absorbing performance can be obtained so that the floatation of the adhesive layer between the display panel and the support plate can be suppressed.

Meanwhile, the indenter push-in amount of a cross-section of the resin layer is 3000 nm or less, preferably 2800 nm or less, and more preferably 2000 nm or less. When the indenter push-in amount of a cross-section of the resin layer is in the above range, the hardness of the hard coating layer surface can be maintained so that high chafing resistance can be obtained.

In the present disclosure, the indenter push-in amount of a cross-section of the resin layer is obtained by measuring the displacement “d” at the time when the indentation test wherein a Berkovitch indenter is pushed-in into the resin layer under a constant load. Specifically, at first, a block wherein a stacked body for a display device cut out to a size of 1 mm×10 mm is embedded in an embedding resin is prepared, and a uniform section with a thickness of 70 nm or more and 100 nm or less without a hole, for example, is cut out from this block by a common section preparing method. For the preparation of the section, Ultramicrotome EM UC7 from Leica Microsystems, Inc. is used. Then, the remaining of the block from which this uniform section without a hole, for example, is cut out is used as a measurement sample. Then, onto the cross-section in such the measurement sample obtained by cutting out the section, using a nanoindenter (TI950 Tribo Indenter from Bruker Corporation), and a Berkovich indenter (a triangular pyramid, TI-0039 from Bruker Corporation) as the indenter is pushed-in perpendicularly onto the center of the cross-section of the resin layer, under the following measurement conditions, taking 40 seconds, until the maximum load of 200 μN, and the displacement (push-in depth) “d” at that time is measured. Here, in order to avoid an influence of the side edge of the resin layer, the Berkovich indenter shall be pushed-in into a portion 500 nm or more away from both side edges of the resin layer respectively toward the center side of the resin layer. The displacement “d” is an arithmetic average value of the value obtained by measuring at ten places. Incidentally, when a value deviating ±20% or more from the arithmetic average value is included in the measured value, that measured value is excluded, and the measurement is carried out again. Whether the value deviating ±20% or more from the arithmetic average value exists in the measured value, or not is determined by finding out whether the value (%) obtained by (A−B)/B×100, when the measured value is regarded as A and the arithmetic average value is regarded as B, is +20% or more, or not.

### (Measurement Conditions)

Controlling method: load control (maximum load of 200 μN)
Lifting amount: 0 nm
Preload: 0.5 μN
Loading speed: 5 μN/second
Retention time at maximum load: 10 seconds
Unloading speed: 5 μN/second
Temperature: 23° C.
Relative humidity: 50%

### 2. Total Light Transmittance

The total light transmittance of the resin layer used in the present disclosure is preferably, for example, 80% or more, more preferably 85% or more, and further preferably 88% or more. When the total light transmittance is high as described above, the stacked body for a display device may have good transparency.

Here, the total light transmittance of the resin layer may be measured according to JIS K7361-1, and may be measure with, for example, a haze meter HM150 from Murakami Color Research Laboratory Co., Ltd.

### 3. Thickness

The thickness of the resin layer in the present disclosure is 5 μm or more, and preferably 10 μm or more. When the thickness is in the above range, a level-difference absorbing performance can be obtained.

Meanwhile, in view of the storage property, for example, into the display device such as slidable display and rollable display, the thickness of the resin layer is preferably thin. Specifically, the thickness is 45 μm or less, may be 35 μm or less, may be 30 μm or less, and may be 25 μm or less. When the thickness is in the above range, good storage property into the display device can be obtained, and the hardness of the hard coating layer surface can be maintained so that chafing resistance can be maintained.

### 4. Material of Resin Layer

The material of the resin layer in the present disclosure is not particularly limited as long as it is transparent material that can make the indenter push-in amount of a cross-section of the resin layer in the range described above, and examples thereof may include urethane based resins, acrylic based gels, and silicone based gels. In the present disclosure, the urethane based resins are preferable, and particularly preferably the ionizing radiation curable urethane based resins and thermoplastic polyurethane (TPU). The urethane based resins are resins including urethane bonding.

The thermoplastic polyurethane is polyurethane that exhibits plasticity by heating, and generally refers to polyurethane having a linear structure whose molecular weight is increased to an extent. The thermoplastic polyurethane can be obtained, for example, by the copolymerization of polyisocyanates, polymer polyols and chain extenders. Examples of the polyisocyanate may include aliphatic, alicyclic or aromatic diisocyanates, and the aromatic diisocyanates are preferable.

As the polymer polyol, polyetherpolyol or polyester polyol preferably having a molecular weight of 500 or more and 8000 or less is preferable, and more preferably approximately 600 or more and 4000 or less. Examples of the polyether polyol may include polyoxy ethylene glycol, polyoxy propylene glycol, polyoxy ethylene oxypropylene glycol, polyoxy tetramethylene glycol, and polyoxy hexamethylene glycol. Among them, polyoxytetramethylene glycol is preferable. As the polyester polyol, aliphatic polyester polyols derived from aliphatic dicarboxylic acids and aliphatic diols are preferable.

The ionizing radiation curable urethane based resin is a cured product of an ionizing radiation curable urethane based resin composition, and in particular, preferably the cured product of an ultraviolet curable urethane based resin composition. The ionizing radiation curable urethane based resin composition includes urethane (meth)acrylate. The urethane (meth)acrylate may be any one of monomers, oligomers, and prepolymers. The number (number of functional groups) of the (meth)acryloyl group in the urethane (meth)acrylate is preferably 2 or more and 4 or less. Incidentally, “(meth)acryloyl group” includes both of “acryloyl group” and “methacryloyl group”. The weight average molecular weight of the urethane (meth)acrylate is preferably 1500 or more and 20000 or less. The ionizing radiation curable urethane based resin composition may include (meth)acrylate compounds. Examples of the (meth)acrylate compound may include monofunctional (meth)acrylate compounds and polyfunctional (meth)acrylate compounds. The ionizing radiation curable urethane based resin composition may include, for example, either one of or both of the monofunctional (meth)acrylate compounds and polyfunctional (meth)acrylate compounds. By adjusting the type or content of the (meth)acrylate compounds, particularly polyfunctional (meth)acrylate compounds, the indenter push-in amount of a cross-section of the resin layer can be adjusted.

As for the acrylic based gels, various polymers obtained by polymerizing monomers including acrylic acid esters, such as those used for adhesives, can be used. Specifically, for example, as the acrylic based gel, ones obtained by polymerizing or copolymerizing acrylic based monomers such as ethyl(meth)acrylate, n-propyl(meth)acrylate, i-propyl(meth)acrylate, n-butyl(meth)acrylate, i-butyl(meth)acrylate, 2-ethylhexyl(meth)acrylate, n-hexyl(meth)acrylate, n-amyl(meth)acrylate, i-amyl(meth)acrylate, octyl(meth)acrylate, i-octyl(meth)acrylate, i-myristyl (meth)acrylate, lauryl(meth)acrylate, nonyl(meth)acrylate, i-nonyl(meth)acrylate, i-decyl(meth)acrylate, tridecyl(meth)acrylate, stearyl(meth)acrylate, and i-stearyl(meth)acrylate, can be used. In the present descriptions, “(meth)acrylate” includes both of “acrylate” and “methacrylate”. Incidentally, the acrylic acid esters used in the above (co) polymerization may be used alone, and two or more types of them may be used together.

Silicone gel refers to ones in solid state obtained by a gelation of silicone oil, and two-liquid addition reaction type silicone gel is preferably used, particularly in view of the absence of reaction byproducts (outgas). The two-liquid addition reaction type silicone gel is obtained by hydrosilylation of a silicone polymer (main agent) including a vinyl group and a silicone polymer (curing agent) including a hydroxyl group, under a platinum catalyst. As raw materials for the two-liquid addition reaction type silicone, conventionally known various silicon compounds can be appropriately selected and used, and silicon compounds commercially available as various silicone materials may be used. Also, the substituent group of the silicon atom is not particularly limited, and examples thereof may include 1-10C alkyl groups such as methyl groups, ethyl groups, and propyl groups; 5-10C cycloalkyl groups such as cyclopentyl groups, and cyclohexyl groups; 2-10C alkenyl groups such as vinyl groups and allylic groups; and 5-20C aryl groups such as phenyl groups and tolyl groups, and in addition to the above, the substituent group may be ones wherein a part of the hydrogen atom of these substituent groups is substituted with other atom or substituent group.

Specific examples of the two-liquid reaction thermal addition type silicone gel may include CF-5106 (product name: Dow Toray Co., Ltd.), KE-1012A/B (product name: Shin-Etsu Silicone), and XE14-685 (A)/(B) (product name: Momentive Performance Materials Worldwide LLC). In these silicone gels, the silicone resins as raw materials are classified into liquid A and liquid B, and these silicone gels can be used by mixing these two liquids in a predetermined ratio.

The resin layer may include, for example, ultraviolet absorbers, spectral transmittance adjusters, antifoulants, inorganic particles and/or organic particles, as long as the indenter push-in amount of a cross-section of the resin layer is in the above range and a transparent resin layer can be obtained.

### 5. Method for Forming Resin Layer

Examples of a method for forming a resin layer in the present disclosure may include a method wherein one surface of the resin substrate is coated with a resin composition, via a primer layer if necessary. The method for applying is not particularly limited as long as it is capable of applying with a desired thickness, and examples thereof may include a general coating method such as a gravure coating method, a gravure reverse coating method, a gravure offset coating method, a spin coating method, a roll coating method, a reverse roll method, a blade coating method, a dip coating method, and a screen printing method.

Also, the resin layer can be formed by a transfer method wherein a resin layer is transferred to one surface of a resin substrate; or a method wherein a film-shaped resin layer is adhered to one surface of a resin substrate via a primer layer.

### II. Resin Substrate

The resin substrate in the present disclosure is disposed between the resin layer and the hard coating layer; has a predetermined film thickness together with the resin layer; and is formed with a material that is harder than the resin layer. Therefore, it is possible to bring relief to the curvature of the region with high curvature that occurs locally due to the supporting plate constituting the caterpillar structure used in the screen enlarging region of, for example, slidable display, and prevent the application of high curvature locally to the hard coating layer. Thereby, occurrence of a crack in the hard coating layer can be suppressed.

### 1. Indenter Push-In Amount of Cross-Section

The indenter push-in amount of a cross-section of the resin substrate in the present disclosure is less than the indenter push-in amount of a cross-section of the resin layer described above. When the indenter push-in amount of a cross-section of the resin substrate is less than the indenter push-in amount of a cross-section of the resin layer, occurrence of a crack in the hard coating layer can be suppressed. The indenter push-in amount of the resin substrate is, for example, less than 200 nm, and preferably 180 nm or less. The method for measuring an indenter push-in amount of a cross-section of the resin substrate is similar to the method described in “I. Resin layer” above.

### 2. Young's Modulus

The Young's modulus of the resin substrate in the present disclosure is preferably 2 GPa or more, more preferably 4 GPa or more, and particularly preferably 5 GPa or more. The reason therefor is to bring relief to the curvature of the region with high curvature that occurs locally, and to prevent the application of high curvature locally to the hard coating layer. Incidentally, the resin substrate of 12 GPa or less is used.

In the present disclosure, the Young's modulus of the resin substrate is measured by the following tensile test method. Firstly, in the tensile test, a sample is obtained by cutting out a resin substrate layer, having a single layer structure, having a size of 0.5 cm×7 cm, from a resin substrate. Then, both ends of the sample are fixed to a chucking jig installed in a Tensilon Universal Testing Instrument (product name “RTC-1310A” from Orientec Co., Ltd.) so that the longitudinal direction of the cut sample is in the tensile direction. Then, a tensile test is carried out by pulling the sample at 25° C. and at tensile speed of 10 mm/minute, using the Tensilon Universal Testing Instrument. Young's modulus is obtained by calculating the slope of the straight line connecting the stress when the strain is 0.05% and the stress when the strain is 0.25%, in accordance with JIS K7161-4, in the stress-strain curve obtained from the above tensile test of the resin substrate layer. The Young's modulus is an arithmetic average value of the value obtained by measuring for 3 times.

### 3. Thickness of Resin Substrate

The thickness of the resin substrate is not particularly limited as long as the total thickness of the resin substrate and resin layer is in the range described later, and is, for example, 20 μm or more, may be 30 μm or more, and may be 65 μm or more. Meanwhile, the thickness is, for example, 125 μm or less, may be 100 μm or less, and may be 80 μm or less.

### 4. Material of Resin Substrate

The resin constituting the resin substrate used in the present disclosure is not particularly limited as long as the indenter push-in amount of a cross-section of the resin substrate is the indenter push-in amount described above, and it is able to obtain a resin substrate having transparency; and examples thereof may include polyester based resins, polyimide based resins, and cellulose based resin.

In the present descriptions, polyimide based resin refers to a polymer including an imide bond in the main chain. Examples of the polyimide based resin may include polyimide, polyamideimide, polyesterimide, and polyetherimide. Examples of the polyester based resin may include polyethylene terephthalate (PET), polypropylene terephthalate, polybutylene terephthalate, and polyethylene naphthalate (PEN). Examples of the cellulose based resin may include triacetyl cellulose (TAC). Among them, polyester based resins are preferable. One type of these resins may be used alone, and two types or more may be used in a combination. Among them, in the present disclosure, polyimide based resins, PET, and TAC are preferably used.

The resin substrate may further include an additive if necessary. Examples of the additive may include ultraviolet absorbers, light stabilizers, antioxidants, inorganic particles, silica fillers for facilitating winding, surfactants for improving film forming property or antifoaming property, and an adhesive improving agent.

### III. Hard Coating Layer

The stacked body for a display device in the present disclosure includes a hard coating layer, on the surface of the resin substrate that is opposite side to the resin layer. The hard coating layer is a member to enhance the surface hardness. By placing the hard coating layer, scratch resistance may be improved.

The hard coating layer in the present disclosure may be a single layer, and may have a multi-layered structure of two layers or more.

### 1. Pencil Hardness

Here, “hard coating layer” is a member configured to increase the surface hardness. Specifically, in a configuration wherein the stacked body for a display device in the present disclosure includes a hard coating layer, “hard coating layer” refers one having a hardness of “H” or more in the pencil hardness test according to JIS K 5600 May 4 (1999).

The pencil hardness of the hard coating layer side surface of the stacked body for a display device in the present disclosure is preferably, for example, H or more, more preferably 2H or more, and further preferably 3H or more.

Here, the pencil hardness is measured by the pencil hardness test specified by JIS K5600-5-4 (1999). Specifically, using a pencil for the test specified by JIS-S-6006, the pencil hardness test specified by JIS K5600-5-4 (1999) is carried out to the hard coating layer side surface of the stacked body for a display device, and the pencil hardness may be determined by evaluating the highest pencil hardness at which the sample is not bruised. The measurement conditions may be angle of 45°, load of 750 g, rate of 0.5 mm/second or more and 1 mm/second or less, and temperature of 23±2° C. As the pencil hardness tester, for example, a pencil scratch hardness tester from Toyo Seiki Seisaku-sho, Ltd. may be used.

### 2. Thickness

The thickness of the hard coating layer may be appropriately selected according to the material of the hard coating layer, the function of the hard coating layer and the use application of the stacked body for a display device. For example, when the material of the hard coating layer is an organic material, the thickness of the hard coating layer is preferably 5 μm or more, and may be 10 μm or more. When the thickness of hard coating layer is the above value or more, chafing resistance can be obtained for sure. Meanwhile, the thickness of the hard coating layer is, for example, 20 μm or less.

Also, for example, when the material of the hard coating layer is an inorganic material, the thickness of the hard coating layer may be several tens of nanometers.

### 3. Material of Hard Coating Layer

As a material of the hard coating layer, for example, organic materials, inorganic materials, and organic-inorganic composite materials may be used.

Among the above, the material of the hard coating layer is preferably an organic material. Specifically, the hard coating layer preferably includes a cured product of a resin composition including a polymerizable compound. The cured product of a resin composition including a polymerizable compound may be obtained by carrying out a polymerization reaction of a polymerizable compound, by a known method, using a polymerization initiator if necessary.

### (1) Polymerizable Compound

The polymerizable compound includes at least one polymerizable functional group in the molecule. As the polymerizable compound, for example, at least one type of radical polymerizable compound and cation polymerizable compound may be used.

The radical polymerizable compound is a compound including a radical polymerizable group. The radical polymerizable group included in the radical polymerizable compound may be any functional group capable of generating a radical polymerization reaction, and is not particularly limited; and examples thereof may include a group including a carbon-carbon unsaturated double bond, and specific examples thereof may include a vinyl group and a (meth)acryloyl group. Incidentally, when the radical polymerizable compound includes two or more radical polymerizable groups, these radical polymerizable groups may be the same, and may be different from each other.

The number of radical polymerizable groups included in one molecule of the radical polymerizable compound is preferably two or more, and more preferably three or more, from the viewpoint of improving the hardness of the hard coating layer.

Among the above, from the viewpoint of high reactivity, the radical polymerizable compound is preferably a compound including a (meth)acryloyl group. For example, a polyfunctional (meth)acrylate monomer and oligomer having a molecular weight of several hundred to several thousand, and including several (meth)acryloyl groups in the molecule may be preferably used; such as those referred to as urethane (meth)acrylate, polyester (meth)acrylate, epoxy (meth)acrylate, melamine (meth)acrylate, polyfluoroalkyl(meth)acrylate, and silicone (meth)acrylate can be preferably used. Also, polyfunctional (meth)acrylate polymers including two or more (meth)acryloyl groups on the side chain of acrylate polymers may also be preferably used. Among the above, polyfunctional (meth)acrylate monomers including two or more (meth)acryloyl groups in one molecule may be preferably used. By the hard coating layer including a cured product of the polyfunctional (meth)acrylate monomers, the hardness of the hard coating layer may be improved so that the close adhesiveness may further be improved. Also, a polyfunctional (meth)acrylate oligomer or polymer including two or more (meth)acryloyl groups in one molecule may also be preferably used. By the hard coating layer including a cured product of the polyfunctional (meth)acrylate oligomer or polymer, the hardness and bending resistance of the hard coating layer may be improved, and further, the close adhesiveness may be improved.

Incidentally, in the present specification, (meth)acryloyl represents each of acryloyl and methacryloyl, and (meth)acrylate represents each of acrylate and methacrylate.

Specific examples of the polyfunctional (meth)acrylate monomer may include those described in, for example, JP-A No. 2019-132930. Among them, those having 3 or more and 6 or less (meth)acryloyl groups in one molecule are preferable from the viewpoint of high reactivity and improving hardness of the hard coating layer, and from the point of close adhesiveness. As such a polyfunctional (meth)acrylate monomer, for example, pentaerythritol triacrylate (PETA), dipentaerythritol hexaacrylate (DPHA), pentaerythritol tetraacrylate (PETTA), dipentaerythritol pentaacrylate (DPPA), trimethylolpropane tri(meth)acrylate, tripentaerythritol octa(meth)acrylate, and tetrapentaerythritol deca(meth)acrylate may be preferably used. In particular, at least one type selected from pentaerythritol tri(meth)acrylate, dipentaerythritol penta(meth)acrylate, and dipentaerythritol hexaacrylate; and PO, EO or caprolactone modified product thereof is preferable.

In order to adjust hardness or viscosity, or to improve close adhesiveness, the resin composition may include a monofunctional (meth)acrylate monomer as the radical polymerizable compound. Specific examples of the monofunctional (meth)acrylate monomer may include those described in, for example, Japanese Patent Application Laid-Open (JP-A) No. 2019-132930.

The cation polymerizable compound is a compound including a cation polymerizable group. The cation polymerizable group included in the cation polymerizable compound may be a functional group capable of generating a cation polymerization reaction, and is not particularly limited; and examples thereof may include an epoxy group, an oxetanyl group, and a vinyl ether group. Incidentally, when the cation polymerizable compound includes two or more cation polymerizable groups, these cation polymerizable groups may be the same, and may be different from each other.

The number of the cation polymerizable groups included in one molecule of the cation polymerizable compound is preferably two or more, and more preferably three or more, from the viewpoint of improving hardness of the hard coating layer.

Also, among the above, as a cation polymerizable compound, a compound including at least one type of an epoxy group and an oxetanyl group as a cation polymerizable group is preferable, and a compound including two or more of at least one type of an epoxy group and an oxetanyl group in one molecule is more preferable. A cyclic ether group such as an epoxy group and an oxetanyl group is preferable from the viewpoint that shrinkage associated with the polymerization reaction is small. Also, a compound including the epoxy group among the cyclic ether groups has advantages in that compounds having various structures may be easily obtained; the durability of the obtained hard coating layer is not adversely affected; and the compatibility with the radical polymerizable compound may be easily controlled. Also, the oxetanyl group among the cyclic ether groups has advantages in that the degree of polymerization is high compared with the epoxy group; the toxicity is low; and when the obtained hard coating layer is combined with a compound including an epoxy group, the network forming rate obtained from the cationic polymerizable compound in the coating film is accelerated, and an independent network is formed without leaving unreacted monomers in the film even in a region mixed with the radical polymerizable compound.

Examples of the cationic polymerizable compound including an epoxy group may include an alicyclic epoxy resins such as polyglycidyl ether of a polyhydric alcohol including an alicyclic ring, or resins obtained by epoxidizing a compound including a cyclohexene ring or a cyclopentene ring, with a suitable oxidizing agent such as hydrogen peroxide and a peracid; an aliphatic epoxy resins such as polyglycidyl ether of aliphatic polyhydric alcohol or alkylene oxide adduct thereof, polyglycidyl ester of aliphatic long-chain polybasic acid, or homopolymer or copolymer of glycidyl (meth)acrylate; and a glycidyl ether type epoxy resin such as glycidyl ether produced by the reaction of bisphenols such as bisphenol A, bisphenol F, and hydrogenated bisphenol A, or derivative thereof such as alkylene oxide adduct and caprolactone adduct with epichlorohydrin, and resins that is novolac epoxy resin and derived from bisphenols.

Specific examples of the cationic polymerizable compound including the alicyclic epoxy resin, the glycidyl ether type epoxy resin, and an oxetanyl group may include those described in, for example, JP-A No. 2018-104682.

Incidentally, the cured product of the resin composition including the polymerizable compound included in the hard coating layer may be analyzed by, for example, a Fourier transform infrared spectroscopy (FTIR) and a pyrolysis gas chromatography mass spectrometry (GC-MS), and the degradant of the polymer may be analyzed using a combination of, for example, a high-speed liquid chromatography, a gas chromatography mass spectrometry, a NMR, an element analyzer, an XPS/ESCA and a TOF-SIMS.

### (2) Polymerization Initiator

The resin composition may include a polymerization initiator if necessary. As the polymerization initiator, a radical polymerization initiator, a cation polymerization initiator, and a radical and cation polymerization initiator may be appropriately selected and used. These polymerization initiators are decomposed by at least one type of light irradiation and heating to generate radicals or cations to cause radical polymerization and cation polymerization to proceed. Incidentally, all of the polymerization initiator may be decomposed and may not be left in the hard coating layer, in some cases.

Specific examples of the radical polymerization initiator, and the cation polymerization initiator may include those described in, for example, JP-A No. 2018-104682.

### (3) Particles

The hard coating layer preferably includes inorganic or organic particles, and more preferably includes inorganic fine particles. By the hard coating layer including the particles, hardness may be improved.

Examples of the inorganic particle may include metal oxide particles such as silica (SiO₂), aluminum oxide, zirconia, titania, zinc oxide, germanium oxide, indium oxide, tin oxide, indium tin oxide (ITO), antimony oxide, and cerium oxide; metal fluoride particles such as magnesium fluoride and sodium fluoride; metal particles; metal sulfide particles; and metal nitride particles. Among them, metal oxide particles are preferable, at least one type selected from silica particles and aluminum oxide particles are more preferable, and silica particles are further preferable. The reason therefor is to obtain excellent hardness.

Also, the inorganic particles are preferably reactive inorganic particles including a reactive functional group which undergoes a cross-linking reaction between the inorganic particles or with at least one type of the polymerizable compound, and has an optical reactivity capable of forming a covalent bond on at least a part of the inorganic particle surface. By undergoing the cross-linking reaction between the reactive inorganic particles or between the reactive inorganic particle and at least one type of the radical polymerizable compound and the cation polymerizable compound, hardness of the hard coating layer may further be improved.

At least a part of the surface of the reactive inorganic particles are covered with an organic component, and include the reactive function group introduced by the organic component, on the surface thereof. As the reactive functional group, for example, a polymerizable unsaturated group is preferably used, and more preferably a photo curable unsaturated group. Examples of the reactive functional group may include ethylenically unsaturated bonds such as (meth)acryloyl groups, vinyl groups, and allyl groups; and epoxy groups.

The reactive silica particle is not particularly limited, and conventionally known ones may be used, and examples thereof may include reactive silica particles described in, for example, JP-A No. 2008-165040. Also, examples of commercially available products of the reactive silica particle may include MIBK-SD, MIBK-SDMS, MIBK-SDL, MIBK-SDZL, all from Nissan Chemical Industry Co., Ltd.; and V8802 and V8803, all from JGC Catalysts and Chemicals Ltd.

Also, although the silica particle may be a spherical silica particle, the silica particle is preferably a deformed silica particle. The spherical silica particle and the deformed silica particle may be mixed. Incidentally, in the present specification, the term deformed silica particle means a silica particle of a shape having random irregularities of potato-like shape on the surface. Since the deformed silica particle has a larger surface area compared with the spherical silica particle, by including such deformed silica particle, the contact area with the resin component, for example, becomes large, so that the hardness of the hard coating layer may further be improved.

Incidentally, whether the silica particle is the deformed silica particle, or not may be confirmed by observing the cross-section of the hard coating layer with an electron microscope.

From the viewpoint of improving hardness, the average particle size of the inorganic particle is preferably 5 nm or more, and more preferably 10 nm or more. When the average particle size of the inorganic particle is too small, the production of the particle is difficult, and the particles may be easily aggregated. Also, from the viewpoint of transparency, the average particle size of the inorganic particle is preferably 200 nm or less, more preferably 100 nm or less, and further preferably 50 nm or less. When the average particle size of the inorganic particle is too large, large irregularities may be formed on the hard coating layer, and the haze may be increased.

Here, the average particle size of the inorganic particles may be measured by observing the cross-section of the hard coating layer with an electron microscope, and the average particle size of arbitrary selected 10 particles is regarded as the average particle size. Incidentally, the average particle size of deformed silica particles is the average value of the maximum value (major axis) and the minimum value (minor axis) of the distances between two points of the outer periphery of the deformed silica particle came up in the cross-sectional microscope observation of the hard coating layer.

The hardness of the hard coating layer may be controlled by adjusting the size and content of the inorganic particles. For example, the content of the silica particles is preferably 25 parts by mass or more, and 100 parts by mass or less, with respect to 100 parts by mass of the polymerizable compound.

### (4) Additives

The hard coating layer used in the present disclosure may include an ultraviolet absorber. Deterioration of the resin layer due to ultraviolet rays may be suppressed. In particular, when the resin layer includes polyimide, color change over time of the resin layer including polyimide may be suppressed. Also, in a display device including a stacked body for a display device, the deterioration of a member placed on the display panel side than the stacked body for a display device, such as a polarizer, due to ultraviolet rays may be suppressed.

Also, the hard coating layer in the present disclosure may include an antifoulant. The stacked body for a display device may be imparted with an antifouling property.

Further, the hard coating layer in the present disclosure may further include a different additive if necessary. The additive is appropriately selected according to the function imparted to the hard coating layer, and is not particularly limited. Examples thereof may include inorganic or organic particles configured to adjust refractive index, infrared absorbers, antiglare agents, antifoulants, antistatic agents, colorants such as blue dyes and violet dyes, leveling agents, surfactants, easy lubricants, various sensitizers, flame retardants, adhesive imparting agents, polymerization inhibitors, antioxidants, light stabilizers, surface modifiers, and spectral transmittance adjusters.

### 4. Method for Forming Hard Coating Layer

Examples of the method for forming a hard coating layer is appropriately selected according to the material, for example, of the hard coating layer, and may include a method wherein the resin substrate is coated with a curable resin composition for a hard coating layer including the polymerizable compounds, for example, and cured; a vapor deposition method; and a sputtering method.

The method for applying the curable resin composition for a hard coating layer on the resin substrate is not particularly limited as long as it is a method capable of applying with a desired thickness, and examples thereof may include a general coating method such as a gravure coating method, a gravure reverse coating method, a gravure offset coating method, a spin coating method, a roll coating method, a reverse roll method, a blade coating method, a dip coating method, and a screen printing method. Also, a transfer method may also be used as a method for forming a coating film of a resin composition for a hard coating layer.

The solvent is removed from the coating film of the curable resin composition for a hard coating layer by drying as necessary. Examples of the drying method may include a reduced-pressure drying method, drying by heating, and a combination of these drying methods. For example, the drying may be carried out by heating at temperature of 30° C. or more and 120° C. or less for 10 seconds or more and 180 seconds or less.

The method for curing the coating film of the curable resin composition for a hard coating layer is appropriately selected according to the polymerizable group of the polymerizable compound, and for example, at least one of a light irradiation, and a heating may be used.

For the light irradiation, for example, ultraviolet rays, visible rays, electron beams or ionizing radiations are mainly used. For an ultraviolet ray curing, for example, ultraviolet rays emitted from light beams such as an ultra-high pressure mercury lamp, a high pressure mercury lamp, a low pressure mercury lamp, a carbon arc, an xenon arc, and a metal halide lamp may be used. The irradiation amount of the energy ray source may be, for example, approximately 50 mJ/cm² or more, and 5000 mJ/cm² or less as an integrated exposure at ultraviolet ray wave length of 365 nm.

When heating, for example, the treatment may be carried out at temperature of 40° C. or more and 120° C. or less. Also, the reaction may be carried out by leaving the coating film to stand for 24 hours or more at room temperature (25° C.).

### IV. Other Layers

The resin layer, resin substrate, and hard coating layer are essential for the stacked body for a display device in the present disclosure, and other layers shown below may be included.

### 1. Adhesive Layer for Adhesion

The stacked body for a display device in the present disclosure may include an adhesive layer for adhesion on the surface of the resin layer that is opposite side to the resin substrate. The stacked body for a display device may be adhered to, for example, a display panel via the adhesive layer for adhesion.

The adhesive used for the adhesive layer for adhesion is not particularly limited as long as it is an adhesive having transparency, and is capable of adhering the stacked body for a display device to, for example, a display panel. Examples thereof may include thermosetting adhesives, ultraviolet curable adhesives, two-liquid curable adhesives, thermal fusion adhesives, and pressure-sensitive adhesives (so-called tackiness agents). Among them, the adhesive layer for adhesion preferably includes pressure-sensitive adhesive, that is, it is preferably a pressure-sensitive adhesive layer. Examples of the pressure-sensitive adhesive used for the pressure-sensitive adhesive layer may include acrylic based pressure-sensitive adhesives, silicone based pressure-sensitive adhesives, rubber based pressure-sensitive adhesives, and urethane based pressure-sensitive adhesives, and may be appropriately selected according to the material of the impact absorbing layer. Among them, an acrylic based pressure-sensitive adhesive is preferable. This is because, an acrylic based pressure-sensitive adhesive has excellent transparency, weather resistance, durability, and heat resistance, and is low cost.

The thickness of the adhesive layer for adhesion is preferably, for example, 10 μm or more and 100 μm or less, more preferably 15 μm or more and 60 μm or less, and further preferably 25 μm or more and 50 μm or less. When the thickness of the adhesive layer for adhesion is too thin, the stacked body for a display device and the display panel may not be adhered sufficiently. Also, when the thickness of the adhesive layer for adhesion is too thick, the flexibility may be deteriorated.

As the adhesive layer for adhesion, for example, an adhesive film may be used. Also, for example, the adhesive layer for adhesion may be formed by coating a supporting body or the polyimide substrate, for example, with an adhesive composition. The stacked body for a display device in the present disclosure may include a peelable separator layer on the surface of the adhesive layer for adhesion that is opposite side to the resin layer.

### 2. Antifouling Layer

The stacked body for a display device in the present disclosure may include an antifouling layer on the surface of the hard coating layer that is opposite side to the resin substrate. By placing the antifouling layer, antifouling property may be imparted to the stacked body for a display device. As the material of the antifouling layer, general materials for the antifouling layer may be applied.

The thickness of the antifouling layer is preferably, for example, 1 nm or more and 30 nm or less, more preferably 2 nm or more and 20 nm or less, and further preferably 3 nm or more and 10 nm or less. When the thickness of the antifouling layer is in the above range, the antifouling property and durability may be improved.

A method for forming an antifouling layer may be appropriately selected according to the material of the antifouling layer, and examples thereof may include a method wherein the hard coating layer is coated with a resin composition for an antifouling layer, and cured; a vacuum deposition method; and a sputtering method.

### 3. Primer Layer

The stacked body for a display device in the present disclosure may include a primer layer between the resin substrate and resin layer. By the primer layer, close adhesiveness between the resin substrate and resin layer may be improved. Also, for the same reason, a primer layer may be included between the resin substrate and hard coating layer.

The material of the primer layer is not particularly limited as long as it is a material capable of improving the close adhesiveness between the resin substrate and resin layer, or the close adhesiveness between the resin substrate and hard coating layer, and examples thereof may include resins. Examples of the resin may include (meth)acrylic resins, urethane resins, (meth)acrylic-urethane copolymers, vinyl chloride-vinyl acetate copolymers, polyesters, butyral resins, chlorinated polypropylenes, chlorinated polyethylenes, epoxy resins, and silicone resins. One type of these resins may be used alone, and two types or more may be used in a combination.

The thickness of the primer layer may be the thickness capable of improving the close adhesiveness between the resin substrate and resin layer, or the close adhesiveness between the resin substrate and hard coating layer, and is, for example, 0.1 μm or more and 10 μm or less, and preferably 0.2 μm or more and 5 μm or less.

Examples of a method for forming a primer layer may include a method wherein the resin substrate is coated with a composition for a primer layer. Examples of the method for applying may include general coating methods such as a gravure coating method, a gravure reverse coating method, a gravure offset coating method, a spin coating method, a roll coating method, a reverse roll coating method, a blade coating method, a dip coating method, and a screen printing method. Also, a transfer method may also be used as the method for forming a primer layer.

### 4. Antireflection Layer

The stacked body for a display device in the present disclosure may include an antireflection layer on the surface of the hard coating layer that is opposite side to the resin substrate. By including the antireflection layer, the reflection of external light can be suppressed, and the visibility can be improved.

For the materials constituting the antireflection layer, materials having a predetermined light transmittance and a predetermined flexibility are preferably used. Since the specific examples of the material may include ones used for general antireflection layers, description thereof is omitted herein.

### V. Others

The stacked body for a display device in the present disclosure further has the following features.

### 1. Total Thickness of Resin Substrate and Resin Layer

In the stacked body for a display device in the present disclosure, the total thickness of the resin substrate and resin layer is 50 μm or more, and preferably 70 μm or more. When the total thickness is in the above range, since the hard coating layer can be prevented from having high curvature locally in the slide bent portion, an occurrence of a crack in the hard coating layer can be suppressed.

Meanwhile, the total thickness is 130 μm or less, and preferably 120 μm or less. When the total thickness is in the above range, the repulsion force against the bending direction can be suppressed, the level-difference of the supporting plate can be followed, and the flotation of the adhesive layer can be suppressed. Also, in the slide bent portion, the elongation of the hard coating layer disposed on the outermost periphery can be suppressed so that an occurrence of a crack can be certainly suppressed.

### 2. Slide Bending Resistance

The stacked body for a display device in the present disclosure preferably has the slide bending resistance described above. Specifically, the slide bending resistance of the stacked body for a display device can be evaluated by carrying out the slide bending test described below. The slide bending test is carried out as follows.

### [Slide Bending Test]

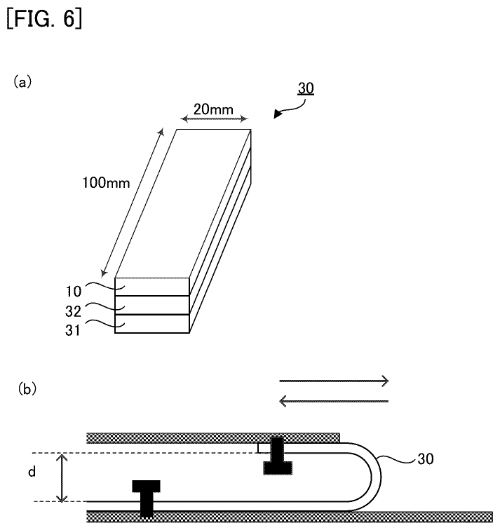

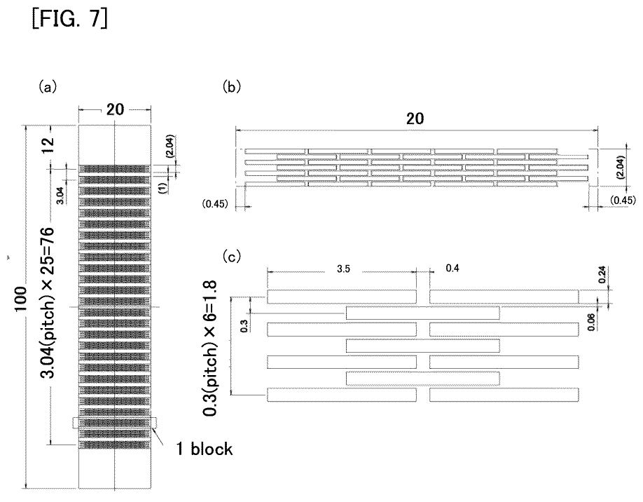

FIG. 6 are schematic views for explaining a slide bending test. Firstly, a stacked body for a display device having a size of 20 mm×100 mm is prepared. As shown in FIG. 6(a), the prepared stacked body for a display device 10 is adhered onto a supporting plate for a test 31 via an adhesive layer for a test 32 to obtain a test piece 30. Here, a schematic top view of the supporting plate for a test 31 is shown in FIG. 7(a). As shown in FIGS. 7, the supporting plate for a test is a SUS304 plate having a thickness of 150 μm, wherein a penetration pattern is formed by etching therethrough. Incidentally, the values in FIG. 7 indicate the length (mm). FIG. 7(b) is a partial enlarged view of 1 block in FIG. 7(a), and FIG. 7(c) is a partial enlarged view of FIG. 7(b). Specifically, the adhesive layer for a test 32 is a pressure-sensitive adhesive 8146-1 (the thickness of the pressure-sensitive adhesive layer, after peeling the separator off, is 25 μm) from 3M.

Then, as shown in FIG. 6(b), the test piece 30 is bent so that the supporting plate for a test 31 is on the inner side, and one end side and another end side in the longitudinal direction are faced each other, and the test piece is set on a slide tester (DMLHB-FU from Yuasa Co., Ltd.) under such condition. Then, with the one end side fixed, the other end side is slid at a slide length (stroke length) of 35 mm, a sliding speed of 30 rpm, and a slide diameter “d” of 8.0 mm (radius of 4.0 mm), and reciprocated repeatedly.

In the stacked body in the present disclosure, it is preferable that, when the slide bending test described above is carried out repeatedly for 200,000 strokes, a flotation of the adhesive layer and a crack in the hard coating layer do not occur.

Also, when the slide diameter “d” is changed to 7 mm (radius of 3.5 mm), and the slide bending test described above is carried out repeatedly for 200,000 strokes, it is more preferable that a flotation of the adhesive layer and a crack in the hard coating layer do not occur.

Particularly, when the slide diameter “d” is changed to 6 mm (radius of 3.0 mm), and the slide bending test described above is carried out repeatedly for 200,000 strokes, it is preferable that a flotation of the adhesive layer and a crack in the hard coating layer do not occur.

### 3. Thickness

The thickness of the stacked body for a display device in the present disclosure is preferably, for example, 55 μm or more and 150 μm or less, more preferably 70 μm or more and 140 μm or less, and further preferably 85 μm or more and 130 μm or less. When the thickness of the stacked body for a display device is in the above range, the flexibility can be improved, and further, it can be easily stored into the display devices such as slidable displays.

### 4. Total Light Transmittance and Haze

The total light transmittance of the stacked body for a display device in the present disclosure is preferably, for example, 80% or more, more preferably 85% or more, and further preferably 88% or more. When the total light transmittance is high as described above, the stacked body for a display device may have good transparency.

Here, the total light transmittance of the stacked body for a display device may be measured according to JIS K7361-1, and may be measure with, for example, a haze meter HM150 from Murakami Color Research Laboratory Co., Ltd.

The haze of the stacked body for a display device in the present disclosure is preferably, for example, 2.0% or less, more preferably 1.5% or less, and further preferably 1.0% or less. When the haze is low as described above, the stacked body for a display device may have good transparency.

Here, the haze of the stacked body for a display device may be measured according to JIS K-7136, and may be measure with, for example, a haze meter HM150 from Murakami Color Research Laboratory Co., Ltd.

### VI. Use Application

The stacked body for a display device in the present disclosure is a member disposed on the observer side than the display panel in a display device. When disposed on the surface of a display device, the stacked body for a display device in the present disclosure is preferably disposed so that the resin layer side surface is on the display panel side and the hard coating layer side surface is on the outer side.

The method for disposing the stacked body for a display device in the present disclosure on the surface of the display device is not particularly limited, and examples thereof may include a method via an adhesive layer. Examples of the adhesive layer may include adhesive layers for adhesions for the stacked body for a display device.

The stacked body for a display device in the present disclosure may be used for a display device used for an electronic device such as smart phones, tablet terminals, wearable terminals, personal computers, televisions, digital signages, public information displays (PIDs), and car mounted displays. Among the above, the stacked body for a display device in the present disclosure may be used for flexible displays, preferably used for slidable displays and rollable displays, and more preferably used for slidable displays.

### B. Display Device

The display device in the present disclosure comprises: a display panel, and the stacked body for a display device described above disposed on an observer side of the display panel.

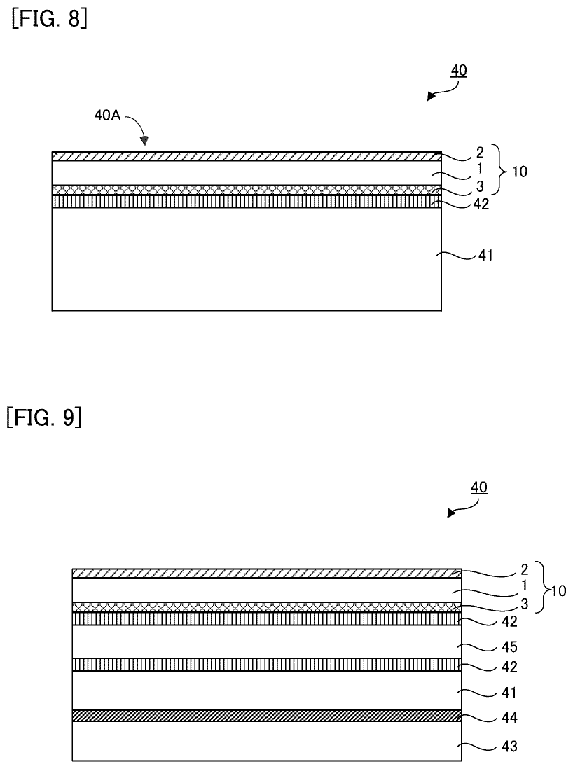

FIG. 8 is a schematic cross-sectional view illustrating an example of a display device in the present disclosure. As shown in FIG. 8, display device 40 comprises display panel 41, and the stacked body for a display device 10 disposed on an observer side of the display panel 41. In the display device 40, the stacked body for a display device 10 and the display panel 41 may be adhered via, for example, the adhesive layer for adhesion 42. In the display device 40, the surface of the hard coating layer 2 of the stacked body for a display device 10 constitutes the surface 40A of the display device 40.

Incidentally, although not shown in the figure here, as described in the section “A. Stacked body for a display device”, the display panel 41 is adhered by an adhesive layer, onto the region to be a bent portion, on the supporting plate including a linear penetration pattern whose longitudinal direction is perpendicular to the screen enlarging direction.

FIG. 9 is a schematic cross-sectional view illustrating another example of a display device in the present disclosure. As shown in FIG. 9, the display device 40 includes a housing 43 in which batteries, for example, are housed, a protective film 44, a display panel 41, a touch-sensitive panel member 45, and a stacked body for a display device 10, in this order. An adhesive layer for adhesion 42 is disposed between the display panel 41 and the touch-sensitive panel member 45 and between the touch-sensitive panel member 45 and the stacked body for a display device 10, and these members are fixed to each other by the adhesive layer for adhesion 42. In this example, the display panel 41 is similarly adhered to the supporting plate, not shown in the figure, by the adhesive layer.

Since the stacked body for a display device in the present disclosure is the similar to those in “A. Stacked body for a display device” above, the descriptions herein will be omitted.

Examples of the display panel in the present disclosure may include a display panel used for a display device such as a liquid crystal display device, an organic EL display device, and a LED display device.

The display device in the present disclosure may include a touch-sensitive panel member between the display panel and the stacked body for a display device.

The display device in the present disclosure is preferably a flexible display. Examples of the flexible displays may include slidable displays, rollable displays, and foldable displays. Among them, the display device in the present disclosure is preferably a display that bends so as the stacked body for a display device is on the outer side, and bends while it slides. That is, the display device in the present disclosure is preferably a slidable display and a rollable display. Since the display device in the present disclosure includes the stacked body for a display device described above, it has excellent chafing resistance and slidable bending resistance, and is suitable as a flexible display, and further as a slidable display and a rollable display.

C. Display Device Provided with Supporting Plate

The display device provided with a supporting plate in the present disclosure comprises a display device, and a supporting plate disposed on a display panel side surface of the display device, wherein the display device is a flexible display; and the supporting plate includes a penetration pattern passing through in the thickness direction.

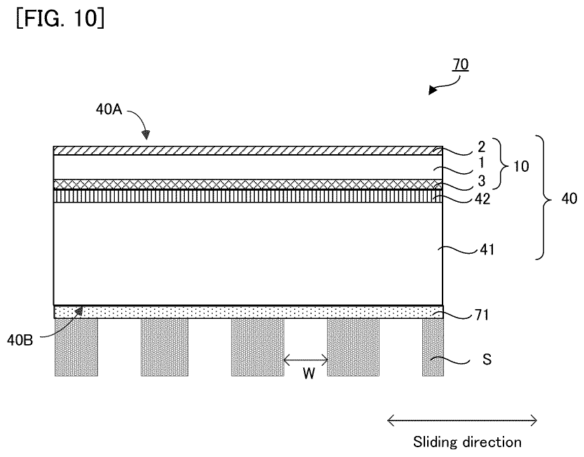

FIG. 10 is a schematic cross-sectional view illustrating an example of a display device provided with a supporting plate in the present disclosure. As shown in FIG. 10, display device provided with a supporting plate 70 comprises the display device 40 described above, and a supporting plate S disposed on a display panel 41 side surface 40B of the display device 40. The “display panel 41 side surface 40B of the display device 40” refers to the surface of the display device 40 located on the display panel 41 side based on the stacked body for a display device 10. The display device 40 is a flexible display. The supporting plate S includes a penetration pattern (through hole) passing through in the thickness direction. Since the supporting plate S includes a penetration pattern, it is easy to bend along with the display device. Meanwhile, since the supporting plate includes the penetration pattern, there is a level-difference wherein the curvature is locally high so that the defects described above are likely to occur. Meanwhile, since the display device provided with a supporting plate in the present disclosure includes the stacked body for a display device described above, the defects in the bent portion (especially in the slide bent portion) can be suppressed for the reasons described above.

The display device in the present disclosure is a flexible display. Examples of the flexible displays may include slidable displays, rollable displays, and foldable displays. Among them, the display is preferably a display that slides and bends while positioned on the supporting plate S. That is, the display device in the present disclosure is preferably a slidable display and a rollable display.

Since other features of the display device are similar to those in “B. Display device” above, the descriptions herein will be omitted.

The supporting substrate is preferably made from metal (such as SUS). The penetration pattern of the supporting plate is preferably a linear penetration pattern, particularly preferably a linear penetration pattern whose longitudinal direction is perpendicular to a sliding direction (screen enlarging direction) (the depth direction of the paper plane in FIG. 10). The supporting substrate preferably includes a plurality of penetration patterns. For example, as the supporting plate for a test shown in FIGS. 7, the supporting plate preferably includes a plurality of blocks including a group of a plurality of closed-packed penetration patterns (through holes) along the sliding direction. The width (reference sign W in FIG. 10) of each penetration pattern in the sliding direction is, for example, 0.1 mm or more, and may be 0.2 mm or more. Meanwhile, the width is, for example, 1 mm or less, and may be 0.5 mm or less. The thickness of the supporting plate is, for example, 100 μm or more, and may be 150 μm or more. Meanwhile, the thickness is, for example, 300 μm or less.

As shown in FIG. 10, an adhesive layer 71 is preferably disposed between the supporting plate S and the display panel 41. Examples of the adhesive layer disposed between the supporting plate and the display panel may include ones similar to the adhesive layer for adhesion described above.

Incidentally, the present disclosure is not limited to the embodiments. The embodiments are exemplification, and any other variations are intended to be included in the technical scope of the present disclosure if they have substantially the same constitution as the technical idea described in the claim of the present disclosure and offer similar operation and effect thereto.

### EXAMPLES

The present disclosure is hereinafter explained in further details with reference to Examples and Comparative Examples.

### Example 1, Examples 3 to 6, Examples 8 to 11, and Comparative Examples 1 to 5

Firstly, as the resin substrate, a PET having the thickness shown in Table 2 was prepared. Using the following composition for a hard coating layer, a hard coating layer was formed on one surface of the resin substrate.

The composition for a hard coating layer and the method for forming a hard coating layer used in Examples and Comparative Examples are as follows.

### <Preparation of Composition for Hard Coating Layer>

Firstly, a composition for a hard coating layer was obtained by compounding each component so as to be the composition shown below.

(Composition for hard coating layer).
Urethane acrylate (product name “UX5000” from Nippon Kayaku Co., Ltd.): 30 parts by mass
Mixture of dipentaerythritol pentaacrylate and dipentaerythritol hexaacrylate (product name “M403” from Toagosei Co., Ltd.): 35 parts by mass.
Polyfunctional acrylate polymer (product name “Acrit 8KX-012C” from Taisei Fine Chemical Co., Ltd.): 35 parts by mass (solid content 100% conversion value).
Fluorine based leveling agent (product name “F568” from DIC Corporation): 0.2 parts by mass (solid content 100% conversion value)
Polymerization initiator (1-hydroxycyclohexylphenyl ketone, product name “Omnirad184” from IGM Resins B. V.): 3 parts by mass
Methyl isobutyl ketone (MIBK): 150 parts by mass

Incidentally, “(solid content 100% conversion value)” is the value when the solid content in the solvent diluted product regarded as 100%.

### <Formation of Hard Coating Layer>

A coating film was formed on one surface of the resin substrate by applying the composition for a hard coating layer with a bar coater. Then, the solvent in the coating film was evaporated by heating the formed coating film for one minute at 70° C. Then, the coating film was completely cured (fully cured) by irradiating ultraviolet rays with an ultraviolet ray irradiation device (light source H bulb from Fusion UV Systems Japan K. K.) under the condition of an oxygen concentration of 200 ppm or less so that the integrated light amount was 300 mJ/cm². Thereby, a hard coating film having a thickness of 5 μm was formed.

Then, using the composition for a resin layer, a resin layer was formed on the surface of the resin substrate that is opposite side to the hard coating layer. Thereby, a stacked body for a display device was obtained.

The composition for a resin layer and the method for forming a resin layer used in Examples and Comparative Examples are as follows.

### <Preparation of Composition for Resin Layer>

Compositions for a resin layer 1 to 6 were obtained by compounding each component so as to be the composition shown in Table 1.
Urethane acrylate 1: urethane acrylate (product name “UV3310B” from Nippon Synthetic Chemical Industry Co., Ltd., bifunctional)
Urethane acrylate 2: urethane acrylate (product name “UV2000B” from Nippon Synthetic Chemical Industry Co., Ltd., bifunctional)
Acrylate compound 1: a mixture of tripentaerythritol acrylate, mono- and di-pentaerythritol acrylate, and polypentaerythritol acrylate (product name Viscoat #802, Osaka Organic Chemical Industry Ltd.)
Acrylate compound 2: ethoxylated pentaerythritol tetraacrylate (product name “ATM-35E” from Shin-Nakamura Chemical Co., Ltd.)
Acrylate compound 3: phenoxyethyl acrylate (product name “Viscoat #192” from Osaka Organic Chemical Industry Ltd.).
Polymerization initiator: 1-hydroxycyclohexylphenyl ketone (product name “Omnirad184” from IGM Resins B. V.)
Antifoulant: product name “BYK-302” from BYK-Chemie Japan Co., Ltd.
Solvent: methyl isobutyl ketone (MIBK)

### <Formation of Resin Layer>

A coating film was formed on the surface of the resin substrate that is opposite side to the hard coating layer by applying the composition for a resin layer shown in Table 2, with a bar coater. Then, the solvent in the coating film was evaporated by heating the formed coating film for 2 minutes at 70° C. Then, the coating film was completely cured (fully cured) by irradiating ultraviolet rays with an ultraviolet ray irradiation device (light source H bulb from Fusion UV Systems Japan K. K.) under the condition of an oxygen concentration of 200 ppm or less so that the integrated light amount was 300 mJ/cm². Thereby, a resin layer having a thickness shown in Table 2 was formed. The total thickness of the resin substrate and resin layer is shown in Table 2.

TABLE 1

| | Compounding amount (parts by mass) | | | | | | | |
|---|---|---|---|---|---|---|---|---|
| | Urethane | Urethane | Acrylate | Acrylate | Acrylate | Polymeri- | | |
| | acrylate | acrylate | compound | compound | compound | zation | Anti- | |
| | 1 | 2 | 1 | 2 | 3 | initiator | foulant | Solvent |
| Resin layer composition 1 | 80 | — | 10 | 5 | — | 3 | 0.01 | 150 |
| Resin layer composition 2 | — | 50 | — | 5 | 45 | 3 | 0.01 | 150 |
| Resin layer composition 3 | 70 | — | — | 20 | 10 | 3 | 0.01 | 150 |
| Resin layer composition 4 | 40 | — | 10 | 50 | — | 3 | 0.01 | 150 |
| Resin layer composition 5 | 10 | — | — | 90 | — | 3 | 0.01 | 150 |
| Resin layer composition 6 | 95 | — | 5 | — | — | 3 | 0.01 | 150 |

### Example 2, Example 7 and Example 12

A stacked body for a display device was obtained in the same manner as in Example 1, except that, instead of forming the resin layer using the composition for a resin layer, a resin layer was formed by slicing a resin film, having a thickness of 100 μm, formed from thermoplastic urethane (product name “DUS270-CER” from Sheedom Co., Ltd.) into a thickness shown in Table 2 (Example 2:35 μm, Example 7:20 μm, Example 12:5 μm), and adhering to the resin substrate.

### [Measurement of Indenter Push-In Amount]

For the stacked body for a display device obtained in Examples 1 to 12 and Comparative Examples 1 to 5, the indenter push-in amount of the cross-section of the resin substrate and resin layer was measured as in the same manner as the method described in “A. Stacked body for display device, 1. Resin layer” above. The results are shown in Table 2.

TABLE 2

| | HC layer | Resin substrate | | | Resin layer | | | Total thickness of |
|---|---|---|---|---|---|---|---|---|
| | Thick- | | Cross-section | Thick- | | Cross-section | Thick- | resin substrate |
| | ness | | indenter push-in | ness | | indenter push-in | ness | and resin layer |
| | [μm] | Type | amount [nm] | [μm] | Resin layer material | amount [nm] | [μm] | [μm] |
| Ex. 1 | 5 | PET | 170 | 65 | Resin layer comp. 1 | 360 | 45 | 110 |
| Ex. 2 | 5 | PET | 170 | 65 | Thermoplastic urethane | 2757 | 35 | 100 |
| Ex. 3 | 5 | PET | 170 | 65 | Resin layer comp. 2 | 485 | 35 | 100 |
| Ex. 4 | 5 | PET | 170 | 65 | Resin layer comp. 3 | 280 | 35 | 100 |
| Ex. 5 | 5 | PET | 170 | 65 | Resin layer comp. 1 | 360 | 30 | 95 |
| Ex. 6 | 5 | PET | 170 | 65 | Resin layer comp. 4 | 252 | 30 | 95 |
| Ex. 7 | 5 | PET | 170 | 65 | Thermoplastic urethane | 2757 | 20 | 85 |
| Ex. 8 | 5 | PET | 170 | 65 | Resin layer comp. 2 | 485 | 20 | 85 |
| Ex. 9 | 5 | PET | 170 | 65 | Resin layer comp. 1 | 360 | 15 | 80 |
| Ex. 10 | 5 | PET | 170 | 23 | Resin layer comp. 1 | 360 | 30 | 53 |
| Ex. 11 | 5 | PET | 170 | 80 | Resin layer comp. 1 | 360 | 40 | 120 |
| Ex. 12 | 5 | PET | 170 | 65 | Thermoplastic urethane | 2757 | 5 | 70 |
| Comp. Ex. 1 | 5 | PET | 170 | 65 | Resin layer comp. 1 | 360 | 55 | 120 |
| Comp. Ex. 2 | 5 | PET | 170 | 65 | Resin layer comp. 6 | 4310 | 30 | 95 |
| Comp. Ex. 3 | 5 | PET | 170 | 65 | Resin layer comp. 5 | 190 | 15 | 80 |
| Comp. Ex. 4 | 5 | PET | 170 | 23 | Resin layer comp. 1 | 360 | 20 | 43 |
| Comp. Ex. 5 | 5 | PET | 170 | 100 | Resin layer comp. 1 | 360 | 40 | 140 |

### [Evaluation]

### (Steel Wool Test (Chafing Resistance Test))

Firstly, a protective film including an adhesive layer on one surface of a PET substrate (thickness of the PET substrate: 100 μm or more and 125 μm or less, thickness of the adhesive layer: 10 μm or more and 25 μm or less) was adhered to the resin layer side surface of the stacked body with a size of 4 cm×10 cm, so as not to cause a curl, and then, the end portion of the stacked body was fixed with cellophane tape on the test stand of Color Fastness Rubbing Tester AB-301 from Tester Sangyo Co., Ltd. Then, using #0000 steel wool (Bonstar #0000 from Nippon Steel Wool Co., Ltd.), the steel wool was fixed to a 2 cm×2 cm jig, the hard coating layer side surface of the stacked body for a display device was rubbed for 1000 strokes under conditions of load of 500 g, reciprocating speed of 40 rpm, reciprocating distance of 40 mm and installation area of the steel wool of 4 cm², at temperature of 23±5° C. and humidity of 40±10% RH. Then, the presence or absence of a scratch was confirmed by transmission and reflection. The results are shown in Table 3.

### (Slide Bending Test)

The slide bending test was carried out to the obtained stacked body to evaluate the bending resistance. Firstly, a stacked body for a display device having a size of 20 mm×100 mm was prepared. As shown in FIG. 6(a), the prepared stacked body for a display device 10 was adhered onto a supporting plate for a test 31 via an adhesive layer for a test 32, so as not to cause a curl, to obtain a test piece 30. For the supporting plate for a test 31, a SUS 304 plate including a penetration pattern shown in FIGS. 7, and having a thickness of 150 μm was used. For the adhesive layer for a test 32, a pressure-sensitive adhesive 8146-1 (the thickness of the pressure-sensitive adhesive layer, after peeling the separator off, was 25 μm) from 3M was used.

Then, as shown in FIG. 6(b), the test piece was bent, so that the supporting plate 31 was on the inner side, to face one end side and another end side in the longitudinal direction each other, and the test piece was set on a slide tester (product name “DMLHB-FU” from Yuasa System Co., Ltd.) under such condition. Then, with the one end side fixed, the other end side was slid at a slide length (stroke length) of 35 mm, a sliding speed of 30 rpm, and a slide diameter “d” of 7.0 mm (radius of 3.5 mm), and reciprocated repeatedly for 200000 (Condition 1). Also, the slide bending test described above was carried out repeatedly for 200,000 strokes under the similar condition except that the slide diameter “d” was changed to 6 mm (radius of 3.0 mm) (Condition 2). Incidentally, the slide diameter “d” was the distance between one end side and the other end side of the stacked body for a display device in the longitudinal direction. The results of the slide bending test were evaluated based on the following criteria.

### Crack Evaluation

A: no cracks occurred in the hard coating layer (HC layer) of the stacked body even under Condition 2.
B: although cracks occurred in the hard coating layer (HC layer) of the stacked body under Condition 2, no cracks occurred under Condition 1.
C: cracks occurred in the hard coating layer (HC layer) of the stacked body under Condition 2 and Condition 1.

### Flotation Evaluation

A: flotation of the adhesive layer from the supporting plate did not occur even under Condition 2.
B: although flotation of the adhesive layer from the supporting plate occurred under Condition 2, float of the adhesive layer did not occur under Condition 1.
C: flotation of the adhesive layer from the supporting plate occurred under Condition 2 and Condition 1.

TABLE 3

Slide bending test

| | Chaffing | HC layer | Adhesive layer |
|---|---|---|---|
| | resistance | crack | flotation |
| Example 1 | No scratch | A | B |
| Example 2 | No scratch | A | A |
| Example 3 | No scratch | A | A |
| Example 4 | No scratch | A | A |
| Example 5 | No scratch | A | A |
| Example 6 | No scratch | B | A |
| Example 7 | No scratch | A | A |
| Example 8 | No scratch | A | A |
| Example 9 | No scratch | B | A |
| Example 10 | No scratch | B | A |
| Example 11 | No scratch | B | A |
| Example 12 | No scratch | A | B* |
| Comp. Ex. 1 | Scratched | A | B |
| Comp. Ex. 2 | Scratched | A | A |
| Comp. Ex. 3 | No scratch | A | C |
| Comp. Ex. 4 | No scratch | C | A |
| Comp. Ex. 5 | No scratch | B | C |

As shown in Table 3, it was confirmed that the chafing resistance in Comparative Example 1 was low, since the thickness of the resin layer was thick. Also, in Comparative Example 2, it was confirmed that the chafing resistance was low, since the indenter push-in amount of the resin layer was too large and was too soft. In Comparative Example 3, the indenter push-in amount of the resin layer was too small and was too hard, causing the adhesive layer to float. In Comparative Example 4, since the total thickness of the resin substrate and resin layer was too thin, sufficient level-difference absorption performance could not be obtained, and a crack occurred in the hard coating layer. In Comparative Example 5, the total thickness of the resin substrate and resin layer was too thick, causing the adhesive layer to float. Examples 1 to 12 showed excellent chafing resistance and the results of the slide bending test were excellent. Incidentally, in Example 12, the thickness of the resin layer was thinner than that of other Examples, and there was a slight flotation of the adhesive layer under Condition 1, but it was not a problem for practical use (B*).

That is, in the present disclosure, the following inventions can be provided.

[1]

A stacked body for a display device comprising:
a resin substrate;
a hard coating layer disposed on one surface of the resin substrate; and
a resin layer disposed on a surface of the resin substrate that is opposite side to the hard coating layer, wherein
an indenter push-in amount of a cross-section of the resin layer is 200 nm or more and 3000 nm or less;
the indenter push-in amount of a cross-section of the resin substrate is less than the indenter push-in amount of a cross-section of the resin layer;
a thickness of the resin layer is 5 μm or more and 45 μm or less; and
a total thickness of the resin substrate and the resin layer is 50 μm or more and 130 μm or less.
   [2]

The stacked body for a display device according to claim 1, wherein the indenter push-in amount of a cross-section of the resin substrate is less than 200 nm.

[3]

The stacked body for a display device according to [1] or [2], wherein the resin substrate includes any one or more of polyethylene terephthalate, triacetylcellulose and polyimide.

[4]

The stacked body for a display device according to any one of [1] to [3], wherein a thickness of the hard coating layer is 5 μm or more and 20 μm or less.

[5]

The stacked body for a display device according to any one of [1] to [4], wherein, when the following slide bending test, of sliding diameter of 7.0 mm, is carried out repeatedly for 200,000 strokes to a test piece produced by adhering the stacked body for a display device on a supporting plate for a test, via an adhesive layer for a test, a peeling of the adhesive layer for a test and a crack in the hard coating layer do not occur.

### [Slide Bending Test]

A test piece is obtained by preparing a stacked body for a display device having a size of 20 mm×100 mm, adhering onto a supporting plate for a test having a thickness of 150 μm, including a penetration pattern, and made from SUS304, via an adhesive layer for a test. The test piece is bent so that the supporting plate for a test is on an inner side, and that one end side and another end side in a longitudinal direction are facing each other, and the test piece is set on a slide tester (DMLHB-FU from Yuasa Co., Ltd.) under such condition. Then, with the one end side fixed, the other end side is slid at a sliding length (stroke length) of 35 mm and a sliding speed of 30 rpm, and reciprocated repeatedly.

[6]

The stacked body for a display device according to any one of [1] to [5], wherein an adhesive layer for adhesion is included on a surface of the resin layer that is opposite side to the resin substrate.

[7]

A display device comprising: a display panel, and the stacked body for a display device according to any one of [1] to [6] disposed on an observer side of the display panel, wherein the stacked body for a display device is disposed so that a hard coating layer side is on an observer side.

[8]

A display device provided with a supporting plate comprising the display device according to [7], and a supporting plate disposed on a display panel side surface of the display device, wherein the display device is a flexible display; and the supporting plate includes a penetration pattern passing through in a thickness direction.

[9]

The display device provided with a supporting plate according to [8], wherein the display device is a display that slides and bends while disposed on the supporting plate.

[10]

The display device provided with a supporting plate according to [9], wherein the penetration pattern is a linear penetration pattern whose longitudinal direction is perpendicular to a sliding direction.

[11]

The display device provided with a supporting plate according to [8] to [10], wherein an adhesive layer is included between the display device and the supporting plate.
1: resin substrate
2: hard coating layer
3: resin layer
10: stacked body for a display device
40: display device
41: display panel
42: optical clear adhesive layer
43: housing
44: protective film
45: touch-sensitive panel member

1. A stacked body for a display device comprising:
a resin substrate;
a hard coating layer disposed on one surface of the resin substrate; and
a resin layer disposed on a surface of the resin substrate that is opposite side to the hard coating layer, wherein
an indenter push-in amount of a cross-section of the resin layer is 200 nm or more and 3000 nm or less;
the indenter push-in amount of a cross-section of the resin substrate is less than the indenter push-in amount of a cross-section of the resin layer;
a thickness of the resin layer is in a range from 5 μm to 45 μm; and
a total thickness of the resin substrate and the resin layer is in a range from 50 μm to 130 μm.

2. The stacked body for a display device according to claim 1, wherein the indenter push-in amount of a cross-section of the resin substrate is less than 200 nm.

3. The stacked body for a display device according to claim 1, wherein the resin substrate comprises at least one material selected from the group consisting of polyethylene terephthalate, triacetylcellulose, and polyimide.

4. The stacked body for a display device according to claim 1, wherein a thickness of the hard coating layer is in a range from 5 μm to 20 μm.

5. The stacked body for a display device according to claim 1, wherein, when the following slide bending test, of sliding diameter of 7.0 mm, is carried out repeatedly for 200,000 strokes to a test piece produced by adhering the stacked body for a display device on a supporting plate for a test, via an adhesive layer for a test, a peeling of the adhesive layer for a test and a crack in the hard coating layer do not occur, where in the
slide bending test:
a test piece is obtained by preparing a stacked body for a display device having a size of 20 mm×100 mm, adhering onto a supporting plate for a test having a thickness of 150 μm, including a penetration pattern, and made from SUS304, via an adhesive layer for a test. The test piece is bent so that the supporting plate for a test is on an inner side, and that one end side and another end side in a longitudinal direction are facing each other, and the test piece is set on a slide tester (DMLHB-FU from Yuasa Co., Ltd.) under such condition, and then with the one end side fixed, the other end side is slid at a sliding length (stroke length) of 35 mm and a sliding speed of 30 rpm, and reciprocated repeatedly.

6. The stacked body for a display device according to claim 1, wherein an adhesive layer for adhesion is included on a surface of the resin layer that is opposite side to the resin substrate.

7. A display device comprising: a display panel, and the stacked body for a display device according to claim 1 disposed on an observer side of the display panel, wherein the stacked body for a display device is disposed so that a hard coating layer side is on an observer side.

8. A display device provided with a supporting plate comprising the display device according to claim 7, and a supporting plate disposed on a display panel side surface of the display device, wherein the display device is a flexible display; and the supporting plate includes a penetration pattern passing through in a thickness direction.

9. The display device provided with a supporting plate according to claim 8, wherein the display device is a display that slides and bends while disposed on the supporting plate.

10. The display device provided with a supporting plate according to claim 9, wherein the penetration pattern is a linear penetration pattern whose longitudinal direction is perpendicular to a sliding direction.

11. The display device provided with a supporting plate according to claim 8, wherein an adhesive layer is included between the display device and the supporting plate.
